(19) United States
(12) Patent Application Publication
(10) Pub. No.: US 2015/0360342 A1
(43) Pub. Date: Dec. 17, 2015

(54) POLISHING PAD

(71) Applicant: TOYO TIRE & RUBBER CO., LTD., Osaka-shi, Osaka (JP)

(72) Inventor: Shinji SHIMIZU, Osaka (JP)

(73) Assignee: TOYO TIRE & RUBBER CO., LTD., Osaka-shi, Osaka (JP)

(21) Appl. No.: 14/761,297

(22) PCT Filed: Jan. 17, 2014
(86) PCT No.: PCT/JP2014/050820

§ 371 Date: Jul. 15, 2015

(30) Foreign Application Priority Data
Jan. 31, 2013 (JP) 2013-017363

(51) Int. Cl. B24B 37/24; H01L 21/306; C08G 18/76; C08G 18/32; C08G 18/34

(52) U.S. Cl. CPC B24B 37/24; C08G 18/3203; C08G 18/341; C08G 18/7621; H01L 21/30625

(57) ABSTRACT

A polishing pad includes a polishing layer, and the polishing layer is formed of a reaction cured body of a polyurethane-forming raw material composition that contains: an isocyanate-terminated prepolymer (A) which is obtained by reacting a prepolymer-forming raw material composition (a) that contains an isocyanate component and a polyester polyol; an isocyanate-terminated prepolymer (B) which is obtained by reacting a prepolymer-forming raw material composition (b) that contains an isocyanate component and a polyether polyol; and a chain extender. The polyether polyol contains a polyether polyol (C) that has a number average molecular weight of 1000 or less and a polyether polyol (D) that has a number average molecular weight of 1900 or more. The reaction cured body has a triple phase separation structure.

### TECHNICAL FIELD

The invention relates to a polishing pad capable of performing planarization of materials requiring a high surface planarity such as optical materials including a lens and a reflecting mirror, a silicon wafer, a glass substrate or an aluminum substrates for a hard disc and a product of general metal polishing with stability and a high polishing efficiency. A polishing pad of the invention is preferably employed, especially, in a planarization step of a silicon wafer or a device on which an oxide layer or a metal layer has been formed prior to further stacking an oxide layer or a metal layer thereon.

### BACKGROUND ART

Typical materials requiring surface flatness at high level include a single-crystal silicon disk called a silicon wafer for producing semiconductor integrated circuits (IC, LSI). The surface of the silicon wafer should be flattened highly accurately in a process of producing IC, LSI etc., in order to provide reliable semiconductor connections for various coatings used in manufacturing the circuits. In the step of polishing finish, a polishing pad is generally stuck on a rotatable supporting disk called a platen, while a workpiece such as a semiconductor wafer is stuck on a polishing head. By movement of the two, a relative speed is generated between the platen and the polishing head while polishing slurry having abrasive grains is continuously supplied to the polishing pad, to effect polishing processing.

As polishing characteristics of a polishing pad, it is requested that a material being polished is excellent in planarity and in-plane uniformity and a polishing rate is large. A planarity and in-plane uniformity of a material being polished can be improved to some extent with a polishing layer higher in elastic modulus. A polishing rate can be bettered by increasing a holding quantity of a slurry on a foam with cells therein.

For example, Patent Document 1 discloses a polishing cloth for use in planarizing a material having a step, which includes a polishing surface having parts with different degrees of surface hardness, wherein the parts with different degrees of surface hardness are formed by phase separation of resin that forms the surface.

Patent Document 2 discloses a polishing pad useful for planarization, which includes a polymer matrix containing a dispersed elastomeric polymer and having a glass transition temperature higher than room temperature, wherein the elastomeric polymer has an average length of at least 0.1 μm in at least one direction, makes up 1 to 45% by volume of the polishing pad, and has a glass transition temperature lower than room temperature.

Considering the development of next-generation devices, there is a demand for high-hardness polishing pads capable of further increasing planarity. In order to increase planarity, non-foamed, hard polishing pads may also be used. In the case where such hard pads are used, however, a problem may occur in which scratches (scars) are more likely to occur on the surface of the material being polished.

Patent Document 3 discloses a polishing pad for use in polishing Cu films, which has a polishing layer made of a polyurethane resin foam so that scratching can be less likely to occur, wherein the polyurethane resin foam is a product of curing reaction of a chain extender with an isocyanate-terminated prepolymer containing an isocyanate component and a high-molecular weight polyol component as raw material components, and the high-molecular weight polyol component contains 30% by weight or more of polyester polyol.

Patent Document 4 discloses a polishing pad having a polishing layer, wherein the polishing layer is formed of a reaction cured body of a polyurethane-forming raw material composition containing: an isocyanate-terminated prepolymer (A) obtained by reaction of a prepolymer-forming raw material composition (a) containing an isocyanate component and a polyester polyol; an isocyanate-terminated prepolymer (B) obtained by reaction of a prepolymer-forming raw material composition (b) containing an isocyanate component and a polyether polyol; and a chain extender; and wherein the reaction cured body has a phase separation structure. Patent Document 4 also describes that the polishing pad can provide a high polishing rate and excellent planarization characteristics, while being capable of suppressing the occurrence of scratches.

### PRIOR ART DOCUMENTS

### Patent Documents

Patent Document 1: JP-A-08-11050
Patent Document 2: JP-A-2008-173760
Patent Document 3: JP-A-2007-42923
Patent Document 3: JP-A-2011-194563

### SUMMARY OF THE INVENTION

### Problems to be Solved by the Invention

The purpose of the present invention is to provide a polishing pad which includes a polishing layer having a triple phase separation structure and has a high polishing rate and excellent planarization characteristics, while being capable of suppressing the occurrence of scratches. Another purpose of the invention is to provide a method of manufacturing a semiconductor device using the polishing pad.

### Means for Solving the Problems

As a result of earnest studies to solve the above problems, the inventors have accomplished the invention based on the finding that the objects can be achieved by the polishing pad described below.

Thus, the invention is directed to a polishing pad having a polishing layer, wherein the polishing layer is formed of a reaction cured body of a polyurethane-forming raw material composition that contains:
an isocyanate-terminated prepolymer (A) which is obtained by reacting a prepolymer-forming raw material composition (a) that contains an isocyanate component and a polyester polyol;
an isocyanate-terminated prepolymer (B) which is obtained by reacting a prepolymer-forming raw material composition (b) that contains an isocyanate component and a polyether polyol; and
a chain extender; wherein
the polyether polyol contains a polyether polyol (C) that has a number average molecular weight of 1000 or less and a polyether polyol (D) that has a number average molecular weight of 1900 or more, and
the reaction cured body has a triple phase separation structure.

By paying attention to properties of polyester polyols and polyether polyols that are incompatible with one another, the present inventors have found that a reaction cured body having a macroscopic triple phase separation structure can be obtained by using, as the starting materials, the isocyanate-terminated prepolymer (A) and the isocyanate-terminated prepolymer (B) that are separately synthesized and reacting these prepolymers with a chain extender and the like, followed by curing. Then, by forming the polishing layer using the reaction cured body, it was found that a polishing pad which has a higher polishing rate and more excellent planarization characteristics, while being capable of suppressing the occurrence of scratches, than the polishing pad including a polishing layer having a double phase separation structure described in Patent Document 4. For more information, surface dressing of the polishing layer is performed very well by dress processing (cutting processing) using a conditioner, thereby to improve the polishing performance, resulting in an extremely larger increase of the polishing rate. Further, since the polishing layer has, as a whole, an extremely high hardness, such a layer is excellent in planarization characteristics and the occurrence of scratches can be effectively suppressed because the polishing layer has in part a low hardness region due to phase separation.

When the number average molecular weight of the polyether polyol (C) is more than 1000, a triple phase separation structure is not formed and a polishing rate cannot be larger, because of which a surface dressing property is deteriorated. In addition, when the number average molecular weight of the polyether polyol (D) is less than 1900, a triple phase separation structure is not formed and a polishing rate cannot be larger, because of which a surface dressing property is deteriorated.

The triple phase separation structure has a first island portion, a second island portion, and a sea portion, wherein the average maximum length of the first island portion is preferably 0.05 to 100 μm and the average maximum length of the second island portion is preferably 0.05 to 100 μm. When the triple phase separation structure is a sea-island structure having the first island portion, the second island portion, and the sea portion, the above effects are further enhanced. The first island portion is a soft phase, the second island portion is a crystalline phase, and the sea portion is a hard phase. It is considered that the first island portion is formed of a reaction cured body composed mainly of an isocyanate-terminated prepolymer (A), the second island portion is formed of a polyether polyol component (D) among the reaction cured bodies composed mainly of an isocyanate-terminatedprepolymer (B), and the sea portion is formed of a hardened portion other than the polyether polyol component (D) among the reaction cured bodies composed mainly of an isocyanate-terminated prepolymer (B). The second island portion which is a crystalline phase is very brittle and susceptible to elimination. Therefore, the surface dressing is very well done by the dress processing, so that the polishing rate was considered to have increased. Moreover, since the first island portion is softer than the sea portion, it is considered that the occurrence of scratches is effectively suppressed.

If the average maximum length of the first island portion is less than 0.05 μm, there is a tendency that the effect of suppressing the occurrence of scratches becomes insufficient. On the other hand, if the average maximum length of the first island portion exceeds 100 μm, the planarization characteristics tend to become worse.

If the average maximum length of the second island portion is less than 0.05 μm, the ability to dress the surface becomes insufficient, so that the polishing rate tends to hardly increase. On the other hand, if the average maximum length of the second island portion exceeds 100 μm, the pad life tends to be short because the wear resistance is lowered.

The content of the polyether polyol (D) is preferably 4 to 50% by weight based on the total weight of the high molecular weight polyol contained in the prepolymer-forming raw material compositions (a) and (b). If the content of the polyether polyol (D) is less than 4% by weight, it tends to be difficult to forma reaction cured body having a triple phase separation structure. On the other hand, if the content of the polyether polyol (D) exceeds 50% by weight, the proportion of the crystalline phase increases and the wear resistance tends to decrease, resulting in the shortening of the pad life.

The content of the polyether polyol (C) is preferably 100 to 1000 parts by weight based on 100 parts by weight of the polyether polyol (D). When the content of the polyether polyol (C) is less than 100 parts by weight, the proportion of the crystalline phase increases and the wear resistance is lowered, so that the pad life tends to be short. When the content of the polyether polyol (C) exceeds 1000 parts by weight, it tends to be difficult to form a reaction cured body having a triple phase separation structure.

The polyurethane-forming raw material composition contains preferably 50 to 500 parts by weight of an isocyanate-terminated prepolymer (B) based on 100 parts by weight of an isocyanate-terminated prepolymer (A). If the isocyanate-terminated prepolymer (B) is contained in an amount of less than 50 parts by weight, it becomes difficult to form a reaction cured body having a triple phase separation structure. And if the content of the isocyanate-terminated prepolymer (B) exceeds 500 parts by weight, the proportion of the soft phase increases and the planarization characteristics tend to deteriorate.

The polyester polyol is preferably at least one member selected from the group consisting of polyethylene adipate glycol, polybutylene adipate glycol, and polyhexamethylene adipate glycol. Also, the polyether polyols (C) and (D) are preferably each a polytetramethylene ether glycol.

The invention is also directed to a method for manufacturing a semiconductor device, which includes the step of polishing the surface of a semiconductor wafer using the above polishing pad.

### BRIEF DESCRIPTION OF THE DRAWINGS

FIG. 1 is a schematic diagram showing an exemplary polishing apparatus used in chemical mechanical polishing (CMP);

FIG. 2 is an image (30 μm×30 μm and 5 μm×5 μm) of the surface of a polishing layer prepared in Example 1, which is measured using a scanning probe microscope; and

FIG. 3 is an image (30 μm×30 μm and 5 μm×5 μm) of the surface of a polishing layer prepared in Example 2, which is measured using a scanning probe microscope.

### MODE FOR CARRYING OUT THE INVENTION

The polishing pad of the invention includes a polishing layer including a polyurethane resin. The polishing pad of the invention may be only the polishing layer or a laminated body of the polishing layer and any other layer (such as a cushion layer).

Polyurethane is a preferred material for forming the polishing layer, because polyurethane is excellent in abrasion resistance and polymers with desired physical properties can be easily obtained by varying the raw material composition.

The polishing layer is made of a reaction cured body of a polyurethane-forming raw material composition that contains: an isocyanate-terminated prepolymer (A) which is obtained by reacting a prepolymer-forming raw material composition (a) that contains an isocyanate component and a polyester polyol; an isocyanate-terminated prepolymer (B) which is obtained by reacting a prepolymer-forming raw material composition (b) that contains an isocyanate component and a polyether polyol; and a chain extender, in which the reaction cured body has a triple phase separation structure.

As the isocyanate component, a compound known in the field of polyurethane can be used without particular limitation. The isocyanate monomer includes, for example, aromatic diisocyanates such as 2,4-toluene diisocyanate, 2,6-toluene diisocyanate, 2,2′-diphenyl methane diisocyanate, 2,4′-diphenyl methane diisocyanate, 4,4′-diphenyl methane diisocyanate, 1,5-naphthalene diisocyanate, p-phenylene diisocyanate, m-phenylene diisocyanate, p-xylylene diisocyanate and m-xylylene diisocyanate, aliphatic diisocyanates such as ethylene diisocyanate, 2,2,4-trimethyl hexamethylene diisocyanate and 1,6-hexamethylene diisocyanate, and cycloaliphatic diisocyanates such as 1,4-cyclohexane diisocyanate, 4,4′-dicyclohexyl methane diisocyanate, isophorone diisocyanate and norbornane diisocyanate. These may be used alone or as a mixture of two or more thereof.

Besides the above diisocyanate, a tri- or polyfunctional isocyanate may also be used.

Examples of the polyester polyol include polyester polyols such as polyethylene adipate glycol, polypropylene adipate glycol, polybutylene adipate glycol, polyhexamethylene adipate glycol, and polycaprolactone polyol; a product of reaction between alkylene carbonate and a polyester glycol such as polycaprolactone polyol; and polyester polycarbonate polyols such as products obtained by a process including allowing a polyhydric alcohol to react with ethylene carbonate and then allowing the resulting reaction mixture to react with an organic dicarboxylic acid. These may be used singly or in combination of two or more. Among them, at least one polyester polyol selected from the group consisting of polyethylene adipate glycol, polybutylene adipate glycol, and polyhexamethylene adipate glycol is preferably used.

The number average molecular weight of the polyester polyol is preferably, but not limited to, 200 to 5,000, more preferably 500 to 2,000, in view of the triple phase separation structure and viscoelastic properties of the polyurethane resin to be obtained. In the case where the number average molecular weight is less than 200, the triple phase separation structure may tend to be difficult to form. On the other hand, in the case where the number average molecular weight is more than 5,000, there may be a tendency to obtain a soft polyurethane resin so that the planarization property may tend to be reduced.

While it is preferred that only the polyester polyol should be added as a high molecular weight polyol to the prepolymer-forming raw material composition (a), any other known high molecular weight polyol (with a number average molecular weight of about 200 to about 5,000) may also be added as long as the objects of the invention are not compromised.

The polyether polyol includes a polyether polyol (C) having a number average molecular weight of 1000 or less and a polyether polyol (D) having a number average molecular weight of 1900 or more.

Examples of the polyether polyol include polyether polyols such as polyethylene glycol (PEG), polypropylene glycol (PPG), polytetramethylene ether glycol (PTMG), and polyhexamethylene ether glycol (PHMG); and polyether polycarbonate polyols such as products obtained by reaction of a diol(s) such as 1,3-propanediol, 1,4-butanediol, 1,6-hexanediol, polypropylene glycol, and/or polytetramethylene glycol with phosgene or a diallyl carbonate (such as diphenyl carbonate) or a cyclic carbonate (such as propylene carbonate). These may be used singly or in combination of two or more. In particular, polytetramethylene ether glycol is preferably used.

The number average molecular weight of the polyether polyol (C) is preferably 850 or less. The number average molecular weight of the polyether polyol (D) is preferably 2000 or more.

The content of the polyether polyol (C) in the prepolymer-forming raw material composition (b) is preferably 100 to 1000 parts by weight based on 100 parts by weight of the polyether polyol (D).

Furthermore, the content of the polyether polyol (D) is preferably 4 to 50% by weight, more preferably 5 to 30% by weight, based on the total weight of the high molecular weight polyols contained in the prepolymer-forming raw material compositions (a) and (b).

It is preferable to add only the polyether polyols (C) and (D) as a high molecular weight polyol to the prepolymer-forming raw material composition (b); however, other known high molecular weight polyols (having a number average molecular weight of about 200 to 5000) may be added so long as they do not impair the purpose of the present invention.

Low molecular weight components (a molecular weight is 200 or less) such as a low molecular weight polyol, a low molecular weight polyamine, and an alcoholamine may also be added to the prepolymer-forming raw material compositions (a) and (b).

Examples of the low molecular weight polyol include ethylene glycol, 1,2-propylene glycol, 1,3-propylene glycol, 1,2-butanediol, 1,3-butanediol, 1,4-butanediol, 2,3-butanediol, 1,6-hexanediol, neopentyl glycol, 1,4-cyclohexanedimethanol, 3-methyl-1,5-pentanediol, diethylene glycol, triethylene glycol, 1,4-bis(2-hydroxyethoxy)benzene, trimethylolpropane, glycerin, 1,2,6-hexanetriol, pentaerythritol, tetramethylolcyclohexane, methylglucoside, sorbitol, mannitol, dulcitol, sucrose, 2,2,6,6-tetrakis(hydroxymethyl)cyclohexanol, diethanolamine, N-methyldiethanolamine, and triethanolamine. One or more of these polyols may be used alone or in any combination.

Examples of the low molecular weight polyamine include ethylenediamine, tolylenediamine, diphenylmethanediamine, diethylenetriamine, etc. These may be used singly or in combination of two or more.

Examples of the alcoholamine include monoethanolamine, 2-(2-aminoethylamino)ethanol, monopropanolamine, etc. These may be used singly or in combination of two or more.

The content of the low molecular weight component in the prepolymer-forming raw material composition (b) is not particularly restricted and may be appropriately determined depending on the properties required of the polishing pad (polishing layer).

In a case where a polyurethane foam is produced by means of a prepolymer method, a chain extender is used in curing of a prepolymer. A chain extender is an organic compound having at least two active hydrogen groups and examples of the active hydrogen group include: a hydroxyl group, a primary or secondary amino group, a thiol group (SH) and the like. Concrete examples of the chain extender include: polyamines such as 4,4′-methylenebis(o-chloroaniline)(MOCA), 2,6-dichloro-p-phenylenediamine, 4,4′-methylenebis(2,3-dichloroaniline), 3,5-bis(methylthio)-2,4-toluenediamine, 3,5-bis(methylthio)-2,6-toluenediamine, 3,5-diethyltoluene-2,4-diamine, 3,5-diethyltoluene-2,6-diamine, trimethylene glycol-di-p-aminobenzoate, polytetramethylene oxide-di-p-aminobenzoate, 4,4′-diamino-3,3′,5,5′-tetraethyldiphenylmethane, 4,4′-diamino-3,3′-diisopropyl-5,5′-dimethyldiphenylmethane, 4,4′-diamino-3,3′,5,5′-tetraisopropyldiphenylmethane, 1,2-bis(2-aminophenylthio)ethane, 4,4′-diamino-3,3′-diethyl-5,5′-dimethyldiphenylmethane, N,N′-di-sec-butyl-4,4′-diaminophenylmethane, 3,3′-diethyl-4,4′-diaminodiphenylmethane, m-xylylenediamine, N,N′-di-sec-butyl-p-phenylenediamine, m-phenylenediamine and p-xylylenediamine; the low moleculer weight polyol; the low molecular weight polyamine and the like. The chain extenders described above may be used either alone or in mixture of two kinds or more.

The mixing ratio of the isocyanate-terminated prepolymer (A), the isocyanate-terminated prepolymer (B), and the chain extender may be varied depending on the molecular weight of each material and the desired physical properties of the polishing pad. The amount of addition of the isocyanate-terminated prepolymer (B) is preferably from 50 to 500 parts by weight, more preferably from 100 to 300 parts by weight based on 100 parts by weight of the isocyanate-terminated prepolymer (A). Further, in order to obtain a polishing pad having desired polishing properties, the number of isocyanate groups (NCO Index) in the prepolymers is preferably from 0.8 to 1.2, more preferably from 0.99 to 1.15 per the number of active hydrogen groups (hydroxyl groups and/or amino groups) in the chain extender. If the number of isocyanate groups is outside the range, insufficient curing could occur so that the required specific gravity or hardness could not be achieved, which tends to decrease the polishing properties.

The polyurethane resin (cured product) is preferably produced by melting method in view of cost, working environment and so on, while it may be produced by application of any known urethane foaming techniques such as melting method and solution technique.

According to the invention, the polyurethane resin production is performed using a prepolymer process. Polyurethane resin produced by prepolymer process has a preferably excellent physical properties.

Note that an isocyanate-terminatedprepolymer (A) and (B) with a molecular weight of the order in the range of from 300 to 5000 is preferable because of excellency in workability and physical properties.

In the invention, the polyurethane resin is produced by curing reaction of a polyurethane-forming raw material composition containing the isocyanate-terminated prepolymer (A), the isocyanate-terminated prepolymer (B), and the chain extender.

The polyurethane resin may be a foamed product or a non-foamed product. The polyurethane resin may be produced by a batch process including measuring and adding each component to a vessel and stirring the components or by a continuous manufacturing process including continuously supplying each component to a stirring apparatus, stirring the components, feeding the liquid mixture, and producing a molded product.

The polishing layer may be produced by a process including adding the isocyanate-terminated prepolymers (A) and (B) to a reaction vessel, then adding the chain extender thereto, stirring them, and then pouring the mixture into a casting mold with a predetermined size to form a polyurethane resin block, and slicing the block using a slicer, or forming thin sheets at the stage of the cast molding. Alternatively, the polyurethane resin as a raw material may be melted and extruded from a T-die to form a sheet-shaped polishing layer directly.

The method of producing the polyurethane foam may be a method of adding hollow beads, a mechanical foaming method (including mechanical frothing), a chemical foaming method, or the like. While any combination of these methods may be used, in particular, a mechanical foaming method is preferably performed using a silicone surfactant comprising a copolymer of polyalkylsiloxane and polyether. Compounds suitable as the silicone surfactant include SH-192 and L-5340 (manufactured by Dow Corning Toray Silicone Co., Ltd.), B8443 and B8465 (manufactured by Goldschmidt Chemical Corporation), etc. The silicone surfactant is preferably added at a concentration of 0.05 to 10% by weight, more preferably 0.1 to 5% by weight, to the polyurethane-forming raw material composition.

Various additives may be mixed; such as a stabilizer including an antioxidant, a lubricant, a pigment, a filler, an antistatic agent and others.

Description will be given of an example of a method of producing a polyurethane foam of a fine cell type constituting a polishing pad (a polishing layer) below. A method of manufacturing such a polyurethane foam has the following steps:

### 1) Foaming Step of Preparing Cell Dispersion Liquid

The step includes adding a silicone surfactant to the first component containing the isocyanate-terminated prepolymers (A) and (B) so that the polyurethane foam will contain 0.05 to 10% by weight of the silicone surfactant and stirring the mixture in the presence of a non-reactive gas to form a cell dispersion liquid in which the non-reactive gas is dispersed in the form of fine cells. In a case where the prepolymer is solid at an ordinary temperature, the prepolymer is preheated to a proper temperature and used in a molten state.

### 2) Curing Agent (Chain Extender) Mixing Step

The second component containing a chain extender is added into the cell dispersion liquid, which is agitated to thereby obtain a foaming reaction liquid.

### 3) Casting Step

The forming reaction liquid is cast into a mold.

### 4) Curing Step

The foaming reaction liquid having been cast into the mold is heated and reaction-cured.

The non-reactive gas used for forming fine cells is preferably not combustible, and is specifically nitrogen, oxygen, a carbon dioxide gas, a rare gas such as helium and argon, and a mixed gas thereof, and the air dried to remove water is most preferable in respect of cost.

As a stirrer for dispersing the silicone surfactant-containing first component to form fine cells with the non-reactive gas, known stirrers can be used without particular limitation, and examples thereof include a homogenizer, a dissolver, a twin-screw planetary mixer etc. The shape of a stirring blade of the stirrer is not particularly limited either, but a whipper-type stirring blade is preferably used to form fine cells. In order to obtain the desired polyurethane foam, the number of revolutions of the stirring blade is preferably from 500 to 2,000 rpm, more preferably from 800 to 1,500 rpm. The stirring time should be appropriately controlled depending on the desired density.

In a preferable mode, different stirrers are used in stirring for forming a cell dispersion liquid in the stirring step and in stirring for mixing an added chain extender in the mixing step, respectively. In particular, stirring in the mixing step may not be stirring for forming cells, and a stirrer not generating large cells is preferably used. Such a stirrer is preferably a planetary mixer. The same stirrer may be used in the stirring step and the mixing step, and stirring conditions such as revolution rate of the stirring blade are preferably regulated as necessary.

In the method of producing the polyurethane foam with fine cells, heating and post-curing of the foam obtained after casting and reacting the forming reaction liquid in a mold until the dispersion lost fluidity are effective in improving the physical properties of the foam, and are extremely preferable. The forming reaction liquid may be cast in a mold and immediately post-cured in a heating oven, and even under such conditions, heat is not immediately conducted to the reactive components, and thus the diameters of cells are not increased. The curing reaction is conducted preferably at normal pressures to stabilize the shape of cells.

A known catalyst promoting polyurethane reaction, such as tertiary amine-based catalysts, may be used. The type and amount of the catalyst added are determined in consideration of flow time in casting in a predetermined mold after the mixing step.

The average cell diameter of the polyurethane foam is preferably from 20 to 70 μm, more preferably from 30 to 60 μm.

The polyurethane foam preferably has an Asker D hardness of 35 to 65 degrees, more preferably 40 to 65 degrees.

The non-foamed polyurethane preferably has an Asker D hardness of 45 to 75 degrees, more preferably 45 to 65 degrees.

The polyurethane foam preferably has a specific gravity of 0.4 to 1.0.

The polishing layer made of the polyurethane resin has a triple phase separation structure. In particular, the triple phase separation structure has a first island portion, a second island portion, and a sea portion, wherein the average maximum length of the first island portion is preferably 0.05 to 100 μm and the average maximum length of the second island portion is preferably 0.05 to 100 μm.

A polishing pad (polishing layer) of the invention is provided with a depression and a protrusion structure for holding and renewing a slurry. Though in a case where the polishing layer is formed with a fine foam, many openings are on a polishing surface thereof which works so as to hold the slurry, a depression and protrusion structure are preferably provided on the surface of the polishing side thereof in order to achieve more of holdability and renewal of the slurry or in order to prevent induction of dechuck error, breakage of a wafer or decrease in polishing efficiency. The shape of the depression and protrusion structure is not particularly limited insofar as slurry can be retained and renewed, and examples include latticed grooves, concentric circle-shaped grooves, through-holes, non-through-holes, polygonal prism, cylinder, spiral grooves, eccentric grooves, radial grooves, and a combination of these grooves. The groove pitch, groove width, groove thickness etc. are not particularly limited either, and are suitably determined to form grooves. These depression and protrusion structure are generally those having regularity, but the groove pitch, groove width, groove depth etc. can also be changed at each certain region to make retention and renewal of slurry desirable.

The method of forming the depression and protrusion structure is not particularly limited, and for example, formation by mechanical cutting with a jig such as a bite of predetermined size, formation by casting and curing resin in a mold having a specific surface shape, formation by pressing resin with a pressing plate having a specific surface shape, formation by photolithography, formation by a printing means, and formation by a laser light using a CO₂ gas laser or the like.

No specific limitation is placed on a thickness of a polishing layer, but a thickness thereof is about 0.8 to 4 mm, preferably 1.5 to 2.5 mm. The method of preparing the polishing layer of this thickness includes a method wherein a block of the fine-cell foam is cut in predetermined thickness by a slicer in a band saw system or a planing system, a method that involves casting resin into a mold having a cavity of predetermined thickness and curing the resin, a method of using coating techniques and sheet molding techniques, etc.

A polishing pad of the invention may also be a laminate of a polishing layer and a cushion sheet adhered to each other.

The cushion sheet (cushion layer) compensates for characteristics of the polishing layer. The cushion layer is required for satisfying both planarity and uniformity which are in a tradeoff relationship in CMP. Planarity refers to flatness of a pattern region upon polishing an object of polishing having fine unevenness generated upon pattern formation, and uniformity refers to the uniformity of the whole of an object of polishing. Planarity is improved by the characteristics of the polishing layer, while uniformity is improved by the characteristics of the cushion layer. The cushion layer used in the polishing pad of the present invention is preferably softer than the polishing layer.

The material forming the cushion layer is not particularly limited, and examples of such material include a nonwoven fabric such as a polyester nonwoven fabric, a nylon nonwoven fabric or an acrylic nonwoven fabric, a nonwoven fabric impregnated with resin such as a polyester nonwoven fabric impregnated with polyurethane, polymer resin foam such as polyurethane foam and polyethylene foam, rubber resin such as butadiene rubber and isoprene rubber, and photosensitive resin.

Means for adhering the polishing layer to the cushion layer include: for example, a method in which a double-sided tape is sandwiched between the polishing layer and the cushion layer, followed by pressing.

The double-sided tape is of a common construction in which adhesive layers are provided on both surfaces of a substrate such as a nonwoven fabric or a film. It is preferable to use a film as a substrate with consideration given to prevention of permeation of a slurry into a cushion sheet.

A polishing pad of the invention may be provided with a double-sided tape on the surface of the pad adhered to a platen. As the double-sided tape, a tape of a common construction can be used in which adhesive layers are, as described above, provided on both surfaces of a substrate. As the substrate, for example, a nonwoven fabric or a film is used. Preferably used is a film as a substrate since separation from the platen is necessary after the use of a polishing pad.

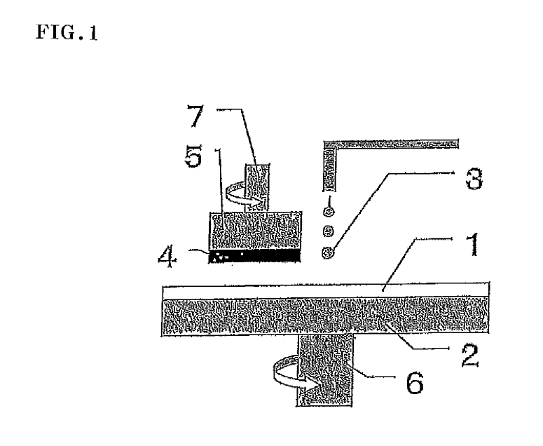

A semiconductor device is fabricated after operation in a step of polishing a surface of a semiconductor wafer with a polishing pad. The term, a semiconductor wafer, generally means a silicon wafer on which a wiring metal and an oxide layer are stacked. No specific limitation is imposed on a polishing method of a semiconductor wafer or a polishing apparatus, and polishing is performed with a polishing apparatus equipped, as shown in FIG. 1, with a polishing platen 2 supporting a polishing pad (a polishing layer) 1, a polishing head 5 holding a semiconductor wafer 4, a backing material for applying a uniform pressure against the wafer and a supply mechanism of a polishing agent 3. The polishing pad 1 is mounted on the polishing platen 2 by adhering the pad to the platen with a double-sided tape. The polishing platen 2 and the polishing head 5 are disposed so that the polishing pad 1 and the semiconductor wafer 4 supported or held by them oppositely face each other and provided with respective rotary shafts 6 and 7. A pressure mechanism for pressing the semiconductor wafer 4 to the polishing pad 1 is installed on the polishing head 5 side. During polishing, the semiconductor wafer 4 is polished by being pressed against the polishing pad 1 while the polishing platen 2 and the polishing head 5 are rotated and a slurry is fed. No specific limitation is placed on a flow rate of the slurry, a polishing load, a polishing platen rotation number and a wafer rotation number, which are properly adjusted.

Protrusions on the surface of the semiconductor wafer 4 are thereby removed and polished flatly. Thereafter, a semiconductor device is produced therefrom through dicing, bonding, packaging etc. The semiconductor device is used in an arithmetic processor, a memory etc.

### EXAMPLES

Description will be given of the invention with examples, while the invention is not limited to description in the examples.

### [Measurement and Evaluation Method]

### (Measurement of Number Average Molecular Weight)

A number average molecular weight was measured by GPC (a Gel Permeation Chromatography) and a value as measured was converted in terms of standard polystylene molecular weight, and the apparatus and conditions in operation were as follows:

GPC apparatus was an apparatus manufactured by Shimadzu Corp., with Model Number of LC-10A.

Columns that were used in measurement were ones manufactured by Polymer Laboratories Co., in which three columns were in connection including (PL gel, 5 μm and 500 Å), (PL gel, 5 μm and 100 Å) and (PL gel, 5 μm and 50 Å).

A flow rate was 1.0 ml/min.

A concentration was 1.0 g/l.

An injection quantity was 40 μl.

A column temperature was 40° C.

An eluent was tetrahydrofuran.

### (Measurement of Average Maximum Length of First Island Portion and Second Island Portion)

The produced, foamed or non-foamed polyurethane was cut into a piece (arbitrary size), and a smooth surface was cut out of the piece under an environment at −80° C. using a diamond knife in an ultramicrotome (LEICA EM UC6, manufactured by Leica). Subsequently, the smooth surface (measurement area: 30 μm×30 μm and 5 μm×5 μm) was measured using a scanning probe microscope (SPM-9500, manufactured by Shimadzu Corporation) and a cantilever (OMCL-AC200TS-R3, manufactured by Olympus Corporation, 9 N/m in spring constant, 150 Hz in resonance frequency) under the conditions of a cantilever scanning speed of 1 Hz and a measurement temperature of 23° C. in the phase detection mode of the viscoelasticity measuring system. When the grayscale range of the resulting image was set at 2 V, image analysis software (WinRoof, Mitani Corporation) was used to display a grayscale image with clearly distinguishable islands. The maximum length of each of ten islands of first island portion and second island portion was measured in the measurement area of 30 μm×30 μm and 5 μm×5 μm, and the average maximum length was calculated from the values.

### (Measurement of Average Cell Diameter)

Using a microtome cutter, the produced polyurethane foam was cut as thin as possible into parallel pieces with a thickness of 1 mm or less, which were used as samples for average cell diameter measurement. The sample was fixed on a slide glass and observed at a magnification of 100 times using an SEM (S-3500N, Hitachi Science Systems, Ltd.). The diameters of all cells in an arbitrary area of the resulting image were measured using image analysis software (WinRoof, Mitani Corporation), and the average cell diameter (μm) was calculated.

### (Measurement of Hardness)

Measurement is conducted according to JIS K6253-1997. The produced polyurethane foam cut out in a size of 2 cm×2 cm (thickness: arbitrary) was used as a sample for measurement of hardness and left for 16 hours in an environment of a temperature of 23±2° C. and a humidity of 50%±5%. At the time of measurement, samples were stuck on one another to a thickness of 6 mm or more. A hardness meter (Asker D Hardness Meter, manufactured by KOBUNSHI KEIKI CO., LTD.) was used. The hardness was measured at ten arbitrary points, and the average value was calculated.

### (Measurement of Specific Gravity)

Determined according to JIS Z8807-1976. The produced polyurethane foam cut out in the form of a strip of 4 cm×8.5 cm (thickness: arbitrary) was used as a sample for measurement of specific gravity and left for 16 hours in an environment of a temperature of 23±2° C. and a humidity of 50%±5%. Measurement was conducted by using a specific gravity hydrometer (manufactured by Sartorius Co., Ltd).

### (Evaluation of Polishing Characteristics)

The prepared polishing pad was used to evaluate polishing characteristics by using a polishing apparatus SPP600S (manufactured by Okamoto Machine Tool Works, Ltd.). The polishing rate was calculated from the polishing amount when an 8-inch silicon wafer on which a thermally oxidized film had been formed to a thickness of 1 μm was polished for 60 seconds. The thickness of the oxidized film was measured by using an optical interference type film thickness meter (device name: Nanospec, manufactured by Nanometrics Inc.). During polishing, silica slurry (SS12 manufactured by Cabot) was added at a flow rate of 150 ml/min. Polishing loading was 350 g/cm², the number of revolutions of the polishing platen was 35 rpm, and the number of revolutions of the wafer was 30 rpm.

The planarization characteristics were evaluated by the cutting amount. A thermally oxidized film was deposited on an 8-inch silicon wafer to a thickness of 0.5 μm, subjected to a predetermined patterning, and then a 1 μm oxidized film was deposited thereon by p-TEOS, to prepare a wafer having a pattern with an initial level difference of 0.5 μm. This wafer was polished under the conditions described above and the cutting amount was calculated by measuring each level difference after the polishing. In two patterns, that is, a pattern having lines of 270 μm in width and spaces of 30 μm arranged alternately and a pattern having lines of 30 μm in width and spaces of 270 μm arranged alternately, the cutting amount means a cutting amount of 270 μm spaces measured when the level difference of the upper part of the lines in the two patterns became 2000 Å or less. A lower cutting amount of 270 μm spaces indicates higher planarity with less cutting amount of regions not intended to be polished.

Evaluation of scratches was carried out by polishing three 8-inch dummy wafers under the above conditions, polishing afterwards an 8-inch wafer on which a thermally oxidized film having a thickness of 10000 Å was deposited, for 1 minute, and measuring the number of scratches of 0.19 μm or more on the polished wafer with use of a surface defect detector (Surfscan SP1, manufactured by KLA-Tencor Corp.).

### Example 1

To a vessel were added 259 parts by weight of toluene diisocyanate (a mixture of 2,4-diisocyanate/2,6-diisocyanate=80/20) and 741 parts by weight of polyethylene adipate glycol with a number average molecular weight of 1,000 and allowed to react at 70° C. for 4 hours, so that an isocyanate-terminated prepolymer (A) was obtained.

To a vessel were added 392 parts by weight of toluene diisocyanate (a mixture of 2,4-diisocyanate/2,6-diisocyanate=80/20), 88 parts by weight of isophorone diisocyanate, 53 parts by weight of polytetramethylene ether glycol having a number average molecular weight of 2000, 106 parts by weight of polytetramethylene ether glycol having a number average molecular weight of 1000, 103 parts by weight of polytetramethylene ether glycol having a number average molecular weight of 650, and 258 parts by weight of polytetramethylene ether glycol having a number average molecular weight of 250, and the mixture was allowed to react at 70° C. for 4 hours, so that an isocyanate-terminated prepolymer (B) was obtained.

To a polymerization vessel were added 33 parts by weight of the prepolymer (A), 67 parts by weight of the prepolymer (B), and 3 parts by weight of a silicone surfactant (B8465, manufactured by Goldschmidt Chemical Corporation) and mixed. The mixture was adjusted to 70° C. in the vessel and was defoamed under reduced pressure. Subsequently, the reaction system was vigorously stirred for about 4 minutes with a stirring blade at a rotational speed of 900 rpm so that air bubbles were incorporated into the reaction system. Thereto was added 27.2 parts by weight of 4,4′-methylenebis(o-chloroaniline) (NCO Index: 1.1), which had been previously melted at 120° C. The liquid mixture was stirred for about 70 seconds and then poured into a loaf-shaped open mold (casting vessel). At the point when the liquid mixture lost its fluidity, it was placed in an oven, and subjected to post curing at 100° C. for 16 hours, so that a polyurethane foam block was obtained.

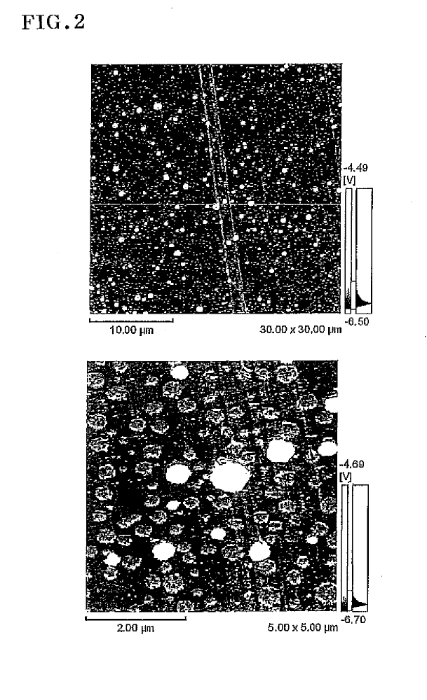

While heated at about 80° C., the polyurethane foam block was sliced using a slicer (VGW-125, manufactured by AMITEC Corporation), so that a polyurethane foam sheet was obtained. Subsequently, the surface of the sheet was buffed using a buffing machine (manufactured by AMITEC Corporation) until its thickness reached 1.27 mm, so that a sheet with regulated thickness accuracy was obtained. The buffed sheet was stamped into a piece with a diameter of 61 cm. Concentric circular grooves with a width of 0.25 mm, a pitch of 1.50 mm, and a depth of 0.40 mm were formed on the surface of the piece using a grooving machine (manufactured by Techno Corporation), so that a polishing layer was obtained. The surface of the polishing layer was a sea-island structure having a first island portion, a second island portion, and a sea portion, wherein the shape of each of the first island portion and the second island portion was circular (see FIG. 2). A double-sided adhesive tape (DOUBLE TACK TAPE, manufactured by SEKISUI CHEMICAL CO., LTD.) was bonded to the opposite surface of the polishing layer from the grooved surface using a laminator. The surface of a corona-treated cushion sheet (Toraypef, a polyethylene foam, 0.8 mm in thickness, manufactured by Toray Industries, Inc.) was also buffed and then bonded to the double-sided adhesive tape using a laminator. A double-sided adhesive tape was further bonded to the other surface of the cushion sheet using a laminator, so that a polishing pad was obtained.

### Examples 2, 3 and Comparative Example 1

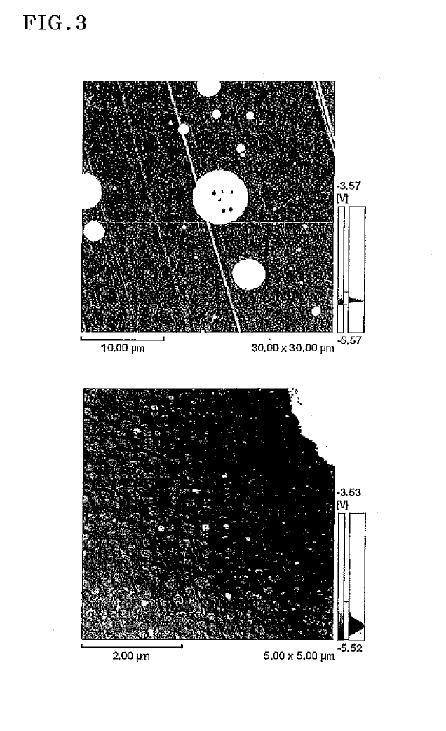

Polishing pads were prepared by the same method as in Example 1, except that the formulations shown in Tables 1 were used instead. In each of Examples 2 and 3, the polishing layer had a triple phase separation structure having a first island portion, a second island portion, and a sea portion. FIG. 3 is an image (30 μm×30 μm and 5 μm×5 μm) obtained by measuring the surface of the polishing layer prepared in Example 2 with a scanning probe microscope. The polishing layer of Comparative Example 1 was a double phase separation structure having an island portion and a sea portion.

TABLE 1

| | | Example | Example | Example | Comparative |
|---|---|---|---|---|---|
| | | 1 | 2 | 3 | example 1 |
| Prepolymer | Toluene diisocyanate | 259 | 259 | 259 | 259 |
| (A) | (part by weight) | | | | |
| | Polyethylene adipate glycol | 741 | 741 | 741 | 741 |
| | (part by weight) | | | | |
| Prepolymer | Toluene diisocyanate | 392 | 432 | 432 | 341 |
| (B) | (part by weight) | | | | |
| | Isophorone diisocyanate | 88 | 97 | 97 | — |
| | (part by weight) | | | | |
| | 4,4′-Dicyclohexylmethane | — | — | — | 76 |
| | diisocyanate (part by weight) | | | | |
| | Polytetramethylene ether glycol | 53 | 234 | 234 | 0 |
| | having Mn of 2000 | | | | |
| | (part by weight) | | | | |
| | Polytetramethylene ether glycol | 106 | 0 | 0 | 528 |
| | having Mn of 1000 | | | | |
| | (part by weight) | | | | |
| | Polytetramethylene ether glycol | 103 | 0 | 0 | 0 |
| | having Mn of 650 | | | | |
| | (part by weight) | | | | |
| | Polytetramethylene ether glycol | 258 | 336 | 336 | 0 |
| | having Mn of 250 | | | | |
| | (part by weight) | | | | |
| | Diethylene glycol | — | — | — | 55 |
| | (part by weight) | | | | |
| Polyurethane | Prepolymer (A) (part by weight) | 33 | 40 | 30 | 25 |
| | Prepolymer (B) (part by weight) | 67 | 60 | 70 | 75 |
| | 4, 4′-Methylenebis (o-chloroaniline) | 27.2 | 26.1 | 28.2 | 24.2 |
| | (part by weight) | | | | |
| | NCO Index | 1.1 | 1.1 | 1.1 | 1.1 |
| | Silicone-based surfactant | 3 | 3 | 3 | 3 |
| | (part by weight) | | | | |
| Physical | Phase separation structure | Triple | Triple | Triple | Double |
| properties of | | phase | phase | phase | phase |
| polishing pad | Average maximum length of first | 0.3 | 0.1 | 0.2 | 30 |
| | island portion (μm) | | | | |
| | Average maximum length of second | 0.5 | 8 | 15 | — |
| | island portion (μm) | | | | |
| | Average cell diameter (μm) | 52 | 53 | 55 | 45 |
| | D hardness (degree) | 57 | 55 | 57 | 48 |
| | Specific gravity | 0.846 | 0.846 | 0.841 | 0.811 |
| | Average polishing rate (Å/min) | 1797 | 1758 | 1727 | 1640 |
| | Cutting amount (Å) | 1020 | 1100 | 1040 | 1250 |
| | Scratch (number/wafer) | 45 | 46 | 54 | 81 |

### INDUSTRIAL APPLICABILITY

A polishing pad of the invention is capable of performing planarization materials requiring a high surface planarity such as optical materials including a lens and a reflective mirror, a silicon wafer, an aluminum substrate and a product of general metal polishing with stability and a high polishing efficiency. A polishing pad of the invention is preferably employed, especially, in a planarization step of a silicon wafer or a device on which an oxide layer or a metal layer has been formed prior to further stacking an oxide layer or a metal layer thereon.

### DESCRIPTION OF REFERENCE SIGNS

1: Polishing pad (Polishing layer)
2: Polishing platen
3: Polishing agent (Slurry)
4: Object to be polished (Semiconductor wafer)
5: Supporting stand (Polishing head)
6, 7: Rotary shafts

1. A polishing pad which comprises a polishing layer, wherein the polishing layer is formed of a reaction cured body of a polyurethane-forming raw material composition that contains:
an isocyanate-terminated prepolymer (A) which is obtained by reacting a prepolymer-forming raw material composition (a) that contains an isocyanate component and a polyester polyol;
an isocyanate-terminated prepolymer (B) which is obtained by reacting a prepolymer-forming raw material composition (b) that contains an isocyanate component and a polyether polyol; and
a chain extender; wherein
the polyether polyol contains a polyether polyol (C) that has a number average molecular weight of 1000 or less and a polyether polyol (D) that has a number average molecular weight of 1900 or more, and
the reaction cured body has a triple phase separation structure.

2. The polishing pad according to claim 1, wherein the triple phase separation structure has a first island portion, a second island portion, and a sea portion; the average maximum length of the first island portion is 0.05 to 100 μm; and the average maximum length of the second island portion is 0.05 to 100 μm.

3. The polishing pad according to claim 1, wherein the content of the polyether polyol (D) is 4 to 50% by weight based on the total weight of a high molecular weight polyol that is contained in the prepolymer-forming raw material compositions (a) and (b).

4. The polishing pad according to claim 1, wherein the content of the polyether polyol (C) is 100 to 1000 parts by weight based on 100 parts by weight of the polyether polyol (D).

5. The polishing pad according to claim 1, wherein the polyurethane-forming raw material composition contains 50 to 500 parts by weight of the isocyanate-terminated prepolymer (B) based on 100 parts by weight of the isocyanate-terminated prepolymer (A).

6. The polishing pad according to claim 1, wherein the polyester polyol is at least one member selected from the group consisting of polyethylene adipate glycol, polybutylene adipate glycol, and polyhexamethylene adipate glycol.

7. The polishing pad according to claim 1, wherein the polyether polyols (C) and (D) are each a polytetramethylene ether glycol.

8. A method for manufacturing a semiconductor device, comprising the step of polishing a surface of a semiconductor wafer using the polishing pad according to claim 1.

9. The polishing pad according to claim 2, wherein the content of the polyether polyol (D) is 4 to 50% by weight based on the total weight of a high molecular weight polyol that is contained in the prepolymer-forming raw material compositions (a) and (b).

10. The polishing pad according to claim 2, wherein the content of the polyether polyol (C) is 100 to 1000 parts by weight based on 100 parts by weight of the polyether polyol (D).

11. The polishing pad according to claim 2, wherein the polyurethane-forming raw material composition contains 50 to 500 parts by weight of the isocyanate-terminated prepolymer (B) based on 100 parts by weight of the isocyanate-terminated prepolymer (A).

12. The polishing pad according to claim 2, wherein the polyester polyol is at least one member selected from the group consisting of polyethylene adipate glycol, polybutylene adipate glycol, and polyhexamethylene adipate glycol.

13. The polishing pad according to claim 2, wherein the polyether polyols (C) and (D) are each a polytetramethylene ether glycol.

14. A method for manufacturing a semiconductor device, comprising the step of polishing a surface of a semiconductor wafer using the polishing pad according to claim 2.

15. The polishing pad according to claim 3, wherein the content of the polyether polyol (C) is 100 to 1000 parts by weight based on 100 parts by weight of the polyether polyol (D).

16. The polishing pad according to any one of claim 3, wherein the polyurethane-forming raw material composition contains 50 to 500 parts by weight of the isocyanate-terminated prepolymer (B) based on 100 parts by weight of the isocyanate-terminated prepolymer (A).

17. The polishing pad according to claim 3, wherein the polyester polyol is at least one member selected from the group consisting of polyethylene adipate glycol, polybutylene adipate glycol, and polyhexamethylene adipate glycol.

18. The polishing pad according to claim 3, wherein the polyether polyols (C) and (D) are each a polytetramethylene ether glycol.

19. A method for manufacturing a semiconductor device, comprising the step of polishing a surface of a semiconductor wafer using the polishing pad according to claim 3.

20. The polishing pad according to any one of claim 4, wherein the polyurethane-forming raw material composition contains 50 to 500 parts by weight of the isocyanate-terminated prepolymer (B) based on 100 parts by weight of the isocyanate-terminated prepolymer (A).
